(19) United States
(12) Patent Application Publication
(10) Pub. No.: US 2005/0170670 A1
(43) Pub. Date: Aug. 4, 2005

(54) Patterning of sacrificial materials

(76) Inventors: William P. King, Atlanta, GA (US); Clifford L. Henderson, Douglasville, GA (US); Harry Dwight Rowland, Atlanta, GA (US); Celesta E. White, Katy, TX (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/990,940

(22) Filed: Nov. 17, 2004

Related U.S. Application Data
(60) Provisional application No. 60/520,810, filed on Nov. 17, 2003.

(51) Int. Cl. H01L 21/311

(52) U.S. Cl. 438/800

(57) ABSTRACT

Methods and compositions for patterning sacrificial materials are provided.

### CROSS-REFERENCE TO RELATED APPLICATION

This application claims the benefit of and priority to U.S. Provisional Patent Application No. 60/520,810 filed on Nov. 17, 2003, which is incorporated by reference in its entirety where permissible.

### BACKGROUND

1. Technical Field

The present disclosure generally relates to methods and systems for producing patterned microstructures and patterned nanostructures.

2. Related Art

Micromachined fluidic systems have applications in, inter alia, chemical synthesis and analysis, biological and chemical sensing, drug delivery, processing of nucleic acids (molecular separation, amplification, sequencing or synthesis), environmental monitoring. The fabrication of these systems is becoming increasingly more problematic as the number of components in the microfluidic systems increases. Integrating these components is a significant obstacle in the development of next generation microfluidic devices.

Integration of various components is generally accomplished using microchannels as conduits. These conduits can be formed by a variety of methods, including for example, using sacrificial materials. U.S. Pat. No. 6,610,593 and U.S. Patent Publication Nos. 20040132855 A1 and 20040146803 to Kohl et al. disclose sacrificial polymers and methods of using them to form microfluidic systems. Polycarbonates have been used as a sacrificial material in fabricating nanofluidic devices by electron beam lithography (C. K. Harnett, et al., J Vac. Sci. Technol. B., vol.19(6), 2842, (2001)).

Another form of lithography, imprint lithography, is a rapidly growing area of research in the electronics industry. To imprint a surface, three basic components are needed: (1) a mechanical “stamp” or mold with relief patterns of the desired features, (2) the material to be imprinted, usually a layer of polymer with suitable glass transition temperature (T_{g}) and molecular weight on an appropriate substrate, and (3) equipment for printing with adequate control of temperature, pressure, and control of parallelism of the stamp and substrate (Sotomayor Torres, C. M., et al., Materials Science & Engineering, C, C23, 23-31 (2003)). In short, the process consists of pressing the stamp into the polymer film using pressures in the range of 5-40 MPa. The polymer film is sometimes heated to aid in the flow of the polymer into the small features of the stamp. The stamp is then detached from the printed substrate after cooling both the stamp and substrate. Combining direct imprinting of sacrificial materials has not been achieved.

### SUMMARY

Aspects of the disclosure generally provide methods and compositions for fabricating patterned structures, for example microstructures, nanostructures, and combinations thereof. One aspect provides a method for producing a patterned structure comprising disposing a sacrificial material on a substrate in a relief pattern; imprinting the relief pattern to form a second pattern; covering the imprinted relief pattern with a second material; and optionally removing the sacrificial material to form a negative of the second pattern in the second material and a negative of the relief pattern in the second material. Selective removal of the sacrificial material forms an air-gap, chamber, channel, or conduit. Alternatively, the sacrificial material can be imprinted and subsequently a pattern, for example a relief pattern is formed therein.

Another aspect provides a device, for example, a microprocessor chip, microfluidic device, sensor, analytical device, semiconductor, MEMS device, containing microstructures and/or nanostructures. In one aspect, the microstructure includes, but is not limited to, a channel or conduit having a dimension of about 1 to about 250 μm and a nanostructure, for example a post, pillar, channel, conduit, or combinations thereof.

Other compositions, methods, features, and advantages will be, or become, apparent to one with skill in the art upon examination of the following figures and detailed description. It is intended that all such additional compositions, methods, features, and advantages be included within this description, be within the scope of the present disclosure, and be protected by the accompanying claims.

### BRIEF DESRCRIPTION OF THE FIGURES

Many aspects of this disclosure can be better understood with reference to the following figures. The components in the figures are not necessarily to scale, emphasis instead being placed upon clearly illustrating the principles of this disclosure. Moreover, in the figures, like reference numerals designate corresponding parts throughout the several views.

FIG. 1A shows a flow diagram of an exemplary method for fabricating patterned sacrificial materials.

FIGS. 1B-H show cross-sectional views that illustrate a representative method for forming chambers in a device.

FIGS. 2A-C show scanning electron micrographs of imprinted sacrificial materials.

FIGS. 3A-C show optical profilometery scans of exemplary imprinted structures in a representative sacrificial material.

FIG. 4 shows an optical micrograph of an exemplary patterned sacrificial material.

FIG. 5 shows optical profilometry of exemplary imprinted sacrificial material.

FIG. 6A shows an scanning electron micrograph of an exemplary silicon master.

FIGS. 6B-C show scanning electron micrographs of exemplary imprinted material.

FIG. 7 shows a scanning electron micrograph of an exemplary microchannel formed with polyimide collapse.

FIG. 8 shows a scanning electron micrograph of an exemplary microchannel with suspended posts.

FIG. 9 shows a scanning electron micrograph of exemplary imprinted sacrificial material prior to the application of an overcoat.

FIG. 10 shows an exemplary process for fabricating microchannels with internal posts using hot embossing of photopatterned sacrificial materials.

FIG. 11A shows an optical micrograph of an exemplary imprinted inlet port through the backside.

FIG. 11B shows a topside view of an optical micrograph of an exemplary imprinted inlet port through the backside

FIG. 11C shows an optical micrograph of an exemplary patterned structure.

FIG. 11D shows a cross-sectional scanning electron micrograph of air channels with polyimide posts formed by the disclosed methods.

FIGS. 12A and B show photographs of exemplary microfluidic devices plumbed to a syringe pump.

FIG. 13 shows an scanning electron micrograph of 10 μm channels fabricated by the disclosed methods.

### DETAILED DESCRIPTION

Methods and compositions for producing patterned structures, for example microfluidic devices having microchannels, nanochannels, microstructures, nanostructures, and combinations thereof are provided. Microstructures, including but not limited to microchannels generally refers to a structure of about 1 to about 250 μm in at least one dimension. A microchannel or microchamber typically has an interior diameter of about 1 to about 250 μm. A nanostructure, including but not limited to a nanochannel, typically has at least one dimension in the range of about 10 to about 900 nm.

The disclosed methods can be used to fabricate a microchannel structure, for example having suspended posts or pillar-like obstructions, microfluidic/nanofluidic combination devices, and achieve resolution improvements of photosensitive sacrificial materials.

A representative device includes a device having a channel disposed in a housing, the channel formed by disposing a sacrificial material in a relief pattern on a surface of the housing; imprinting the relief pattern to form a second pattern; covering the imprinted relief pattern with a second material; and removing the sacrificial material to form the channel.

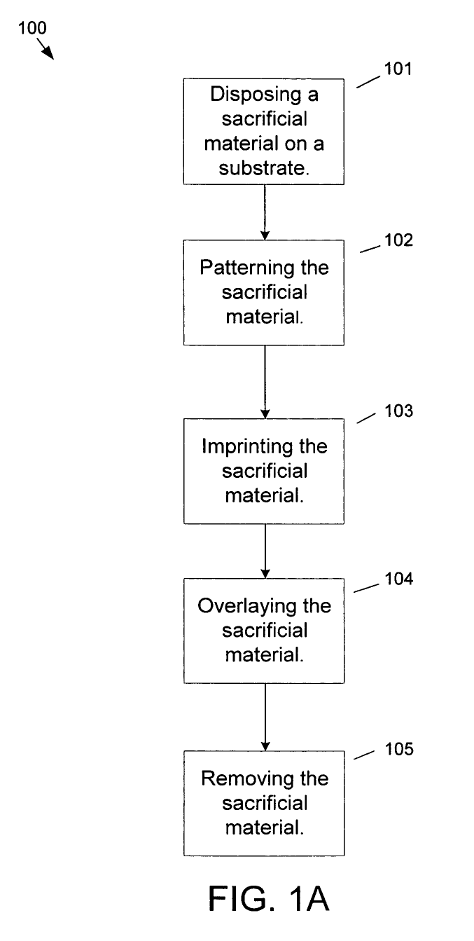

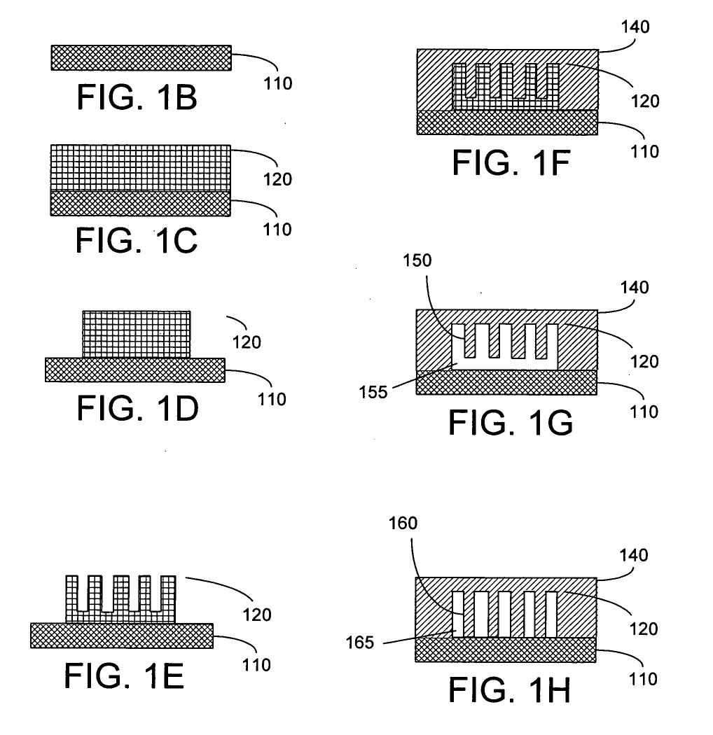

FIG. 1 shows an exemplary method for producing patterned structures, for example, a microfluidic device. Process 100 provides a general overview of an exemplary process for producing pattern structures and begins by applying a sacrificial material, for example a sacrificial polymer, onto a substrate 110 (FIG. 1C). Each of the elements of the exemplary process will be described in more detail below.

The sacrificial material can be patterned as shown in step 102. It will be appreciated that the sacrificial material can also be applied to substrate 110 in a specific pattern, or patterned after application to the substrate, for example using conventional lithography techniques. In one embodiment, application of the sacrificial material to substrate 110 produces a relief pattern. A relief pattern generally refers to a three-dimensional pattern that is typically raised above the surface in contact with the sacrificial material (FIG. 1D). Generally, the relief pattern will be in the pattern of an intended channel, chamber, or air-gap to be incorporated in a resulting device. The patterning of the sacrificial material can be achieved by removing portions of the sacrificial material applied to substrate 110. Depending on the sacrificial material used, areas of the applied sacrificial material can be selectively removed by exposing these regions to a solvent, chemical, electromagnetic energy, heat, or other means for removing the sacrificial material.

In step 103 patterned sacrificial material is imprinted to form an imprinted pattern in the sacrificial material. In one embodiment, the imprinted pattern typically will be an impression used to form a nanostructure, for example a post or partition, to be formed within a microchannel. FIG. 1E shows a sacrificial material 120 imprinted to form a comb-like structure. The imprinted pattern can be imprinted to varying depths of the sacrificial material, and typically the imprinted depth is adjusted to correspond to the dimensions of the desired structure, for example a nanostructure, to be formed. In another embodiment, the depth of the imprinted pattern can be modulated with, for example, a plasma etch process or descum.

The imprinted sacrificial material can then be covered with an overcoat layer 140 as shown in FIG. 1F and step 104 of FIG. 1A. In one embodiment, the overcoat layer includes, but is not limited to, a polymer, thermoplastic, thermoset, elastomer, plastic, polysiloxane, polyimide, polybenzoxazole, spin-on-glass, glass, metal oxide, metal, or a combination thereof. The overcoat can be cured, if necessary.

After overcoating the imprinted sacrificial material, the sacrificial material is removed by process 105. The sacrificial material can be removed by causing the sacrificial material to become more fluid or to change to a fluid, for example a liquid or a gas. The fluid can then travel through substrate 110 or encapsulating layer 140, for example by diffusion or capillary action. Alternatively, the fluid can be removed through a pore, vent, chamber or conduit. Removing the sacrificial material results in the formation of a hollow chamber, channel, or structure molded in the shape of the imprinted sacrificial material.

FIG. 1G shows an exemplary structure formed by the one embodiment of the disclosure. The structure contains posts 150 within a chamber or channel 155. In this embodiment, posts 150 do not contact substrate 110. FIG. 1H shows an alternative structure in which removal of the sacrificial material results in partitions 160 creating multiple channels 165.

Having generally described a representative process for forming patterned structures, the components of the patterned structures will be more fully described.

Sacrificial Materials

Sacrificial material generally refers to a material that can change from a rigid configuration to a flowable configuration, for example from a solid state to a fluid state. Fluid states include liquid states as well as gas states. Representative sacrificial materials include, but are not limited to, a sacrificial composition comprising a polymer, and optionally one or more components that enable pattern formation in the polymer in either a positive tone or negative tone fashion using localized radiation or energy, and those disclosed in U.S. Pat. No. 6,610,593 and U.S. Patent Publication Nos. 20040132855 A1 and 20040146803 to Kohl et al. each of which is incorporated herein by reference in their entirety. The component that provides positive tone patterning of the polymer can include a photoacid generator, for example.

In general, the photoacid generator can be used to make the sacrificial polymer easier to remove (e.g., less stable towards a solvent or more thermally unstable). For example, half of a layer of a sacrificial composition (e.g., a sacrificial polymer and a positive tone component) is exposed to energy, either in the form of thermal energy (e.g., increased temperature) or optical energy (e.g., ultraviolet (UV) light, near-ultraviolet light, and/or visible light), while the other half is not exposed. Subsequently, the entire layer is exposed to a solvent or heat and the solvent or heat dissolves or volatilizes the layer exposed to the energy.

Although not intending to be bound by theory, upon exposure to optical energy, a photoacid generator generates an acid. In a positive tone composition containing a polymer and a photoacid generator, exposure to optical or thermal energy and the subsequent production of acid in the composition can render the exposed polymer composition more soluble in solvent or less stable towards various forms of energy such as heat. Thus, upon exposure to a solvent (e.g. such as a base), The dissolution rate of the exposed sacrificial polymer may be increased relative to the sacrificial composition not exposed to the optical or thermal energy. Likewise, in a positive tone composition containing a polymer and a photoacid generator, exposure to optical or thermal energy and the subsequent production of acid in the composition can render the exposed polymer composition less stable towards thermal or chemical decomposition. For example, the presence of acid in the exposed regions may catalyze the thermal decomposition of the sacrificial polymer at a lower temperature than the unexposed sacrificial composition. Thus, upon exposure to heat or an appropriate chemical, the exposed sacrificial polymer can be decomposed and selectively removed relative to the sacrificial composition not exposed to the optical or thermal energy. As a result, a mask, for example, can be used to fabricate three-dimensional structures from the sacrificial composition by removing the exposed sacrificial polymer.

In general, negative tone compositions can be used making the sacrificial polymer more difficult to remove (e.g., more stable towards a solvent or heat that normally would dissolve or volatilize the sacrificial polymer). For example, half of a layer of a sacrificial composition (including a sacrificial polymer and a negative tone photoinitiator) is exposed to optical energy, while the other half is not exposed. Subsequently, the entire layer is exposed to a solvent or heat and the solvent or heat dissolves or volatilizes the layer not exposed to the optical energy.

More specifically, the area exposed includes a cross-linked photodefinable polymer, while portions not exposed include an uncross-linked photodefinable polymer. The uncross-linked photodefinable polymer can be removed with the solvent leaving the cross-linked photodefinable polymer behind (e.g., a photodefinable three-dimensional structure).

Although not intending to be bound by theory, upon exposure to optical energy, one type, among others, of the negative tone photoinitiator can generate free radicals that initiate cross-linking reactions between the sacrificial polymers to form a cross-linked photodefinable polymer. Therefore, a mask, for example, can be used to fabricate photodefinable three-dimensional structures from the photodefinable polymer by removing the uncross-linked photodefinable polymer.

In general, the sacrificial composition can be used in areas such as, but not limited to, microelectronics (e.g., microprocessor chips, communication chips, and optoeletronic chips), microfluidics, sensors, analytical devices (e.g., microchromatography), as a sacrificial material to create three-dimensional structures that can subsequently have air-regions formed therein (also referred to herein interchangeably as “air-gaps,” “air cavities,” and/or “air channels”) by thermally decomposing the sacrificial polymer. In addition, the sacrificial polymer can be used as an insulator, for example.

In one embodiment, the decomposition of the sacrificial composition can produce gas molecules small enough to permeate one or more of the materials surrounding the sacrificial composition (e.g., an overcoat layer). In addition, the sacrificial composition preferably decomposes slowly, so as not to create undue pressure build-up while forming the air-region within the surrounding materials. In another embodiment, the sacrificial composition can have a decomposition temperature less than the decomposition or degradation temperature of the surrounding material. The sacrificial composition also desirably has a decomposition temperature above the deposition or curing temperature of an overcoat material but less than the degradation temperature of the components in the structure in which the sacrificial composition is being used.

The sacrificial polymer can include compounds such as, but not limited to, polynorbornenes, polycarbonates, functionalized compounds of each, a copolymer of polynorbornene and polynorbornene carbonate, and combinations thereof. The polynorbornene can include, but is not limited to, an alkenyl-substituted norbornene (e.g., cyclo-acrylate norbornene). The polycarbonate can include, but is not limited to, polypropylene carbonate (PPC), polyethylene carbonate (PEC), polycyclohexane carbonate (PCC), polycyclohexanepropylene carbonate (PCPC), and polynorbornene carbonate (PNC), and combinations thereof. Specific polycarbonates that may be used as the disclosed sacrificial polymer include, for example, poly[(oxycarbonyloxy-1,1,4,4-tetramethylbutane)-alt-(oxycarbonyloxy-5-norbornene-2-endo-3-endo-dimethane)]; poly[(oxycarbonyloxy-1,4-dimethylbutane)-alt-(oxycarbonyloxy-5-norbornene-2-endo-3-endo-dimethane)]; poly[(oxycarbonyloxy-1,1,4,4-tetramethylbutane)-alt-(oxycarbonyloxy-p-xylene)]; and poly[(oxycarbonyloxy-1,4-dimethylbutane)-alt-(oxycarbonyloxy-p-xylene)]. In general, the molecular weight of the disclosed sacrificial polymers is from about 10,000 to about 200,000.

The sacrificial polymer can be from about 1% to 50% by weight of the sacrificial composition. In particular, the sacrificial polymer can be from about 5% to 40% by weight of the sacrificial composition.

As mentioned above, the sacrificial composition can include either a negative tone component and/or a positive tone component. The negative tone component can include compounds that generate a reactant that would cause the crosslinking in the sacrificial polymer. The negative tone component can include compounds, such as, but not limited to, a photosensitive free radical generator. Alternative negative tone components can be used, such as photoacid generators (e.g., in epoxide-functionalized systems).

A negative tone photosensitive free radical generator is a compound which, when exposed to light breaks into two or more compounds, at least one of which is a free radical. In particular, the negative tone photoinitiator can include, but is not limited to, bis(2,4,6-trimethylbenzoyl)-phenylphosphineoxide (Irgacure 819, Ciba Specialty Chemicals Inc.); 2-benzyl-2-dimethylamino-1-(4-morpholinophenyl)-butanone-1 (Irgacure 369, Ciba); 2,2-dimethoxy-1,2-diphenylethan-1-one (Irgacure 651, Ciba); 2-methyl-1[4-(methylthio)- phenyl]-2-morpholinopropan-1-one (Irgacure 907, Ciba); benzoin ethyl ether (BEE, Aldrich); 2-methyl-4′-(methylthio)-2-morpholino-propiophenone; 2,2′-dimethoxy-2-phenyl-acetophenone (Irgacure 1300, Ciba); 2,6-bis(4-azidobenzylidene)-4-ethylcyclohexanone (BAC-E), and combinations thereof.

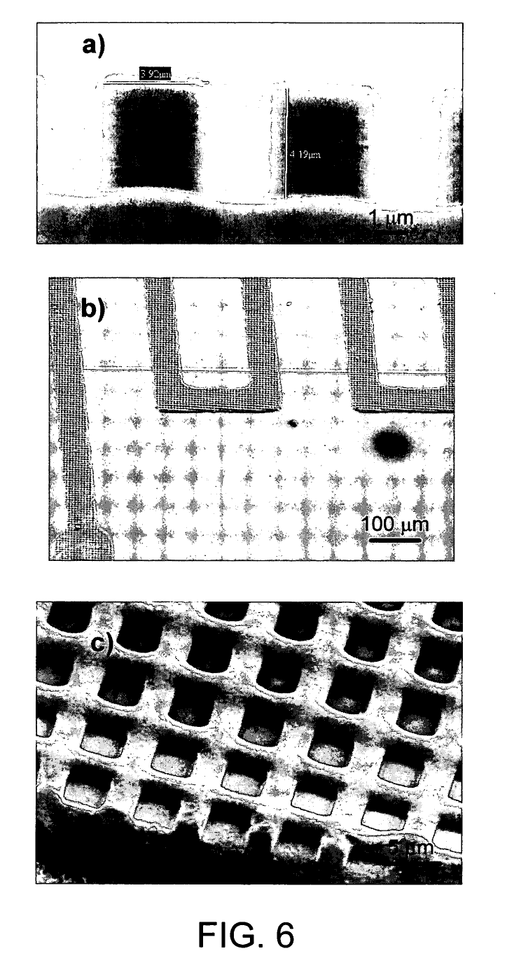

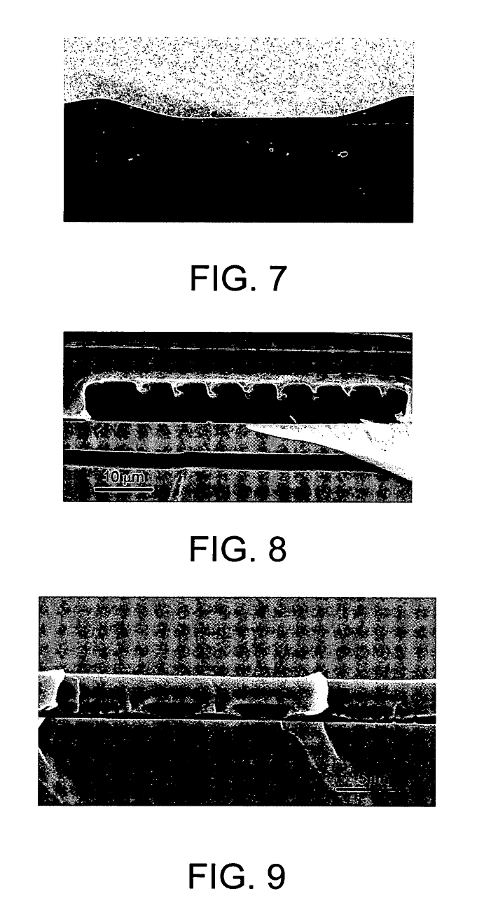

The positive tone component can include, but is not limited to, photoacid generator(s). More specifically, the positive tone photoacid generator can include, but is not limited to, nucleophilic halogenides (e.g., diphenyliodonium salt, diphenylfluoronium salt) and complex metal halide anions (e.g., triphenylsulphonium salts). In particular, the photoacid generator can be tetrakis(pentafluorophenyl)borate-4-methylphenyl[4-(1-methylethyl)phenyl] iodonium (DPI-TPFPB); tris(4-t-butylphenyl)sulfonium tetrakis-(pentafluorophenyl)borate (TTBPS-TPFPB); tris(4-t-butylphenyl)sulfonium hexafluorophosphate (TTBPS-HFP); triphenylsulfonium triflate (TPS-Tf); bis(4-tert-butylphenyl)iodonium triflate (DTBPI-Tf); triazine (TAZ-101); triphenylsulfonium hexafluoroantimonate (TPS-103); Rhodosil™ Photoinitiator 2074 (FABA); triphenylsulfonium bis(perfluoromethanesulfonyl) imide (TPS-N1); di-(p-t-butyl) phenyliodonium bis(perfluoromethanesulfonyl) imide (DTBPI-N1); triphenylsulfonium; tris(perfluoromethanesulfonyl) methide (TPS-C1); di-(p-t-butylphenyl)iodonium tris(perfluoromethanesulfonyl)methide (DTBPI-C1); and combinations thereof, the chemical structures of which are depicted in FIGS. 6 and 7.

The positive or negative tone component can be from about 0.1% to about 10% or about 1% by weight of the sacrificial composition, typically about 3% by weight of the sacrificial composition. In a particular embodiment, the photoacid generator can be from about 1% to about 3% by weight of the sacrificial composition.

The remaining percentage of the sacrificial composition not accounted for in the photoacid generator and sacrificial polymer (e.g., from about 50% to about 99%) can be made up with solvent, such as, but not limited to, mesitylene, N-methyl-2-pyrrolidinone, propylene carbonate, anisole, cyclohexanone, propylene glycol monomethyl ether acetate, N-butyl acetate, diglyme, ethyl 3-ethoxypropionate, and combinations thereof.

Patterning Sacrificial Materials

The patterning, for example relief patterning, of the sacrificial materials can be accomplished using a variety of conventional techniques depending on the properties of the sacrificial material used. In one embodiment, the sacrificial material 120 is patterned by applying conventional optical lithography techniques to substrate 110. For example, when a negative tone sacrificial composition is used, the sacrificial composition can be exposed to a crosslinking or polymerizing amount of electromagnetic radiation, for example ultraviolet radiation, in a patternwise manner. The sacrificial material exposed to the electromagnetic radiation can crosslink or polymerize while the material that is not exposed remains unreacted and of lower molecular weight. A mask in a desired pattern can be employed to prevent regions corresponding to the mask shape from being exposed. The remaining lower molecular weight sacrificial material can then be readily removed by methods such as washing in an appropriate solvent. Typically, the sacrificial material is patterned on a micro-scale, for example, on a scale for creating channels or conduits having an interior hollow diameter of about 1 to about 250 μm.

Alternatively, the sacrificial material can be chemically patterned by exposing specific regions to a chemical that dissolves, etches, or removes the sacrificial material. Ablation techniques can also be employed including laser ablation, chipping, sanding, scouring, ion beam etching, or other forms of physical removal of the sacrificial material. Local thermal heating (e.g. through laser exposure or direct or indirect exposure to heated instruments) of the sacrificial material can also be used to locally decompose the sacrificial material resulting in the formation of patterns. The sacrificial material can also be patterned using a conventional lithographic process which would for example employ exposure and patterning of a masking layer such as a photoresist and subsequent etching of the underlying sacrificial polymer through the patterned masking layer. Likewise, the sacrificial polymer could be covered with a “hard mask” material such as a metal oxide, metal, or glass that is first patterned and etched using conventional lithographic techniques, and this patterned hard mask is then used as an etch mask for patterning the sacrificial polymer.

Imprinting Techniques

The sacrificial material can be further patterned using conventional imprinting techniques, including, but not limited to lithographic techniques. In one embodiment, the imprinting process is on a smaller scale than other patterning of the sacrificial material. In one embodiment, the imprinting pattern is on a nano-scale. Imprinting is typically performed using a master having a desired pattern, for example a nanopattern, that is transferred to the sacrificial material by pressing the master into the sacrificial material. Generally, a sacrificial material is selected that can withstand imprinting conditions, for example pressure and temperature conditions needed to imprint or emboss the sacrificial material.

The imprint master can contain a pattern of arrayed structures, for example microstructures or nanostructures, including posts, pillars, and the like in any geometric configuration. The distance between the nanostructures can be varied according to the ultimate use of the finished structure. For example, an array of nanostructures can be used to form an array of projections in a microchannel. The array of projections can act as a sieve for separating materials that pass through the microchannel, for example polynucleotides. The pattern of the nanostructures can be configured to preferentially sort materials based on size or confirmation. The imprint master can be completely or partially embossed into the sacrificial material, for example to vary the dimension of the posts or pillars formed in the resulting channel.

Dimensions of patterns used in imprinting have features that at least form one full feature or one full channel within the channel. Feature sizes range from 20-150 nm in at least one dimension and can also range from 1-100 μm. Other patterns besides posts could include lines/walls, cones, other three-dimensionally shaped surfaces that vary in their feature height above the substrate, spiral channels, or combinations thereof.

Substrate

Substrate 110 on which the sacrificial composition is disposed can be used in systems such as, but not limited to, microprocessor chips, microfluidic devices, sensors, analytical devices, and combinations thereof. Thus, substrate 110 can be made of materials appropriate for the particular desired system or device. Exemplary materials, however, include, but are not limited to, glasses, silicon, silicon compounds, germanium, germanium compounds, gallium, gallium compounds, indium, indium compounds, or other semiconductor materials and/or compounds. In addition, substrate 110 can include non-semiconductor substrate materials, including any dielectric material, metals (e.g., copper and aluminum), ceramics, or organic materials found in printed wiring boards, for example.

Overcoat Layer

Overcoat layer 140 can be a polymer, for example a modular polymer that includes the characteristic of being permeable or semi-permeable to the decomposition gases produced by the decomposition of a sacrificial polymer while forming the chambers 155 or 165. In addition, overcoat layer 140 can have elastic properties so as to not rupture or collapse under fabrication and use conditions. In one embodiment, overcoat layer 140 is stable under conditions, for example temperature, in which the sacrificial composition decomposes.

Examples of the overcoat layer 140 include compounds such as, but not limited to, polyimides, polynorbornenes, epoxides, polyarylenes ethers, polyarylenes, plastic, thermoplastic, elastomers, polysiloxanes, acrylates, polymethacrylates, inorganic glasses, and combinations thereof. More specifically the overcoat layer 140 includes compounds such as PI2556, Amoco Ultradel™ 7501, Promerus Avatrel™ Dielectric Polymer, DuPont 2611, DuPont 2734, DuPont 2771, DuPont 2555, silicon dioxide, silicon nitride, and aluminum oxide. The overcoat layer 140 can be deposited onto the substrate 110 using techniques such as, for example, spin coating, doctor-blading, sputtering, lamination, screen or stencil-printing, chemical vapor deposition (CVD), metalorganic chemical vapor deposition (MOCVD), and plasma-based deposition systems.

It should be noted that additional components could be disposed on and/or within the substrate 110, the overcoat layer 140, and/or the chamber or channels 155 or 165. In addition, the additional components can be included in any structure having air-regions as described herein. The additional components can include, but are not limited to, electronic elements (e.g., switches and sensors), mechanical elements (e.g., gears and motors), electromechanical elements (e.g., movable beams and mirrors), optical elements (e.g., lens, gratings, and mirror), opto-electronic elements, fluidic elements (e.g., chromatograph and channels that can supply a coolant), and combinations thereof.

It should also be noted that the process can be reversed. In particular, the sacrificial material can be disposed on a substrate, imprinted and then a relief pattern can be formed in the material, followed by covering the imprinted relief pattern with a second material and selectively removing at least a portion of the sacrificial material to form a negative of the imprinted relief pattern.

### EXAMPLES

### Example 1

### Imprinting of Photosensitive Polynorbornene

Samples were examined with scanning electron microscopy [SEM] (Hitachi 3500 Scanning Electron Microscope), optical profilometry (Wyko NT3300 Optical Profilometer), and optical microscopy (Olympus Vanox Microscope).

Avatrel® 2000P dielectric polymer was used as received from Promerus Electronic Materials for film thicknesses larger than 8 μm. For films in the 3-6 μm thickness range, the Avatrel® 2000P was diluted to 33 wt % polymer in mesitylene (Sigma-Aldrich). Avatrel® 1000 Developer (Promerus Electronic Materials) and Pyralin® P12525 and PI2556 polyimides (HD MicroSystems) were used as received.

To study the effects of exposure dose on the imprinting capabilities of a negative tone photosensitive polymer, Avatrel® 2000P (Promerus Electronic Materials) was spin-cast onto a 4″ bare silicon <100>wafer (4000 RPM) to a thickness of approximately 8 μm. The wafer was soft-baked at 110° C. for 8 minutes to remove residual casting solvent. An ACCUDOSE 9000 i-line exposure tool (Oriel Instruments) with a 500W Hg short arc lamp source was used to create a 5×5 dose array of 1 cm square pads with doses ranging from 2-500 mJ/cm². The unfiltered spectral output of this tool covers the entire emission spectrum of Hg arc lamp sources (250-460 nm). Band-pass filters with center wavelengths of 436 nm (g-line) or 365 nm (i-line) can be used when specific exposure wavelengths are desired. Exposure dose was controlled by programming the Accudose software to open and close the shutter at specific space increments and time intervals.

A 15 minute post-exposure bake at 120° C. was applied to the wafer before immersion development with Avatrel® 1000 Developer for 90 s. The wafer was then washed with isopropanol and dried on a CEE spinner. The pads were then diced and imprinted at a constant temperature and pressure.

As an initial study into the use of imprinting techniques for use in the fabrication of microfluidic devices, Avatrel® 2000P was patterned into serpentine channel structures with expanded square ends for use as future inlet and outlet ports. For these tests, Avatrel® 2000P was spin-cast (4-8 μm) onto a 4″ silicon <100> wafer. The wafer was soft-baked at 120° C. for 5 minutes to remove residual casting solvent. The wafer was exposed through a dark field mask to 350 mJ/cm² on a MA6 Mask Aligner (Karl Suss) centered at 405 nm. A 15 minute post-exposure bake at 120° C. was applied to the wafer before submersion developing with Avatrel® 1000 Developer for 90 s. The wafer was then washed with isopropanol to fully develop the pattern.

For the patterned microfluidic channel imprinting, silicon masters were fabricated with square post features of heights ranging from 4 to 7 um. A <100> silicon wafer with 1000 Å of oxide was photolithographically patterned and subsequently wet etched with a buffered oxide etch for 2 min. The posts were drilled out by a Bosch process deep reactive ion etch with an etch rate of 0.3 μm per cycle for 20 cycles. The fabrication resulted in 1×2 cm fields with features of width 1 to 3 μm and periodicity 4 to 6 μm. A reactive ion etch with SF₆ plasma for 60 sec smoothed out the scallops produced by the Bosch process to prevent re-entrant angle problems during the imprint process. Scanning electron micrographs of the silicon masters are shown in FIG. 6.

To perform the hot embossing imprint process, a controlled-heating, force-sensing system was constructed. A one-ton arbor press houses the printing setup. The driving piston of the press is fitted with a precision-flattened stainless steel disc. Underneath the disc rests a thermally resistive, compliant rubber that ensures a smooth application of imprint force and thermally insulates the master and sample from the metal press during embossing. The base of the press supports an S-type force transducer with an accuracy of 1 N up to a load limit of 4 kN. A stainless steel cup with a center locator sits atop the sensor, and a layer of compliant rubber on a thermally insulating glass ceramic sits in the stainless steel cup. The rubber is slotted to house a thin film heater and connections to a high output DC power supply. Immediately above the heater is another thin, slotted stainless steel disc on which the silicon masters used for imprinting rest. Thermocouple wires are soldered into the underside of the disc. The sample to be imprinted is placed face down on the master, and the application of heat and force transfers the feature pattern from master to sample.

Hot embossing of the Avatrel® 2000P was carried out at temperatures ranging from 60° C. to 100° C. with loads ranging from 25 MPa to 40 MPa. Typical load times and load rates were 150-250 seconds and 1-2 MPa/s, respectively. After the load and heat were removed from the master and sample, a cooling time of 10 minutes was allowed before the master and sample were demolded.

After imprinting, the channels were encapsulated by either depositing silicon dioxide using a Plasma Enhanced Chemical Vapor Deposition (PECVD) system or by spin-coating and curing a polyimide film. For the polyimide overcoated samples, films of Pyralin® PI2556 or PI2525 were spin-cast to give the desired film thickness according to the process guide available from HD Microsystems. These parameters are summarized in Table 1. After coating the samples, the polyimide was soft-cured at 120° C. in a standard convection oven and hard-cured in a Lindberg tube furnace under nitrogen purge at 200° C. for 30 minutes and 300° C. for 30 minutes before decomposition of the sacrificial polymer. The furnace program used for all samples is similar to that used by Wu and co-workers^{9,10} for photosensitive PNBs with different photosensitive functionalities but similar thermal properties and is as follows:

(1) Ramp 4° C./min to 200° C., hold 30 minutes

(2) Ramp 2° C./min to 300° C., hold 30 minutes

(3) Ramp 2° C./min to 350° C., no hold

(4) Ramp 1° C./min to 375° C., hold 40 minutes

(5) Ramp 1° C./min to 400° C., hold 40 minutes

(6) Ramp 1° C./min to 450° C., hold 40 minutes

(7) Cool gradually to less than 100° C.

TABLE 1
Spin programs for polyimide overcoat materials

Polyimide

| | |
|---|---|
| PI 2556 | PI 2525 |

Thickness

| | 2 μm | 5 μm |
|---|---|---|
| vel/0 | 500 RPM | 500 RPM |
| RMP/0 | 500 RPM/s | 500 RPM/s |
| time/0 | 5 s | 5 s |
| vel/1 | 500 RPM | 1000 RPM |
| RMP/1 | 1000 RPM/s | 5000 RPM/s |
| time/1 | 30 s | 30 s |

### Example 2

### Effects of Imprint Depth with Varying Exposure Dose

The Avatrel® 2000P sacrificial material used in this work is an epoxide-functionalized polynorbornene loaded with a photoacid generator compound which promotes crosslinking upon exposure to UV light. The mechanical properties of this negative tone system are greatly influenced by the degree of crosslinking in the polymer¹¹. This degree of cross-linking can be altered by varying the processing parameters used, including soft bake time and temperature, exposure dose, and post-exposure bake time and temperature¹². When considering the imprinting capabilities of this type of polymer, it is important to understand how the cross-link density affects the depth of the printed structure.

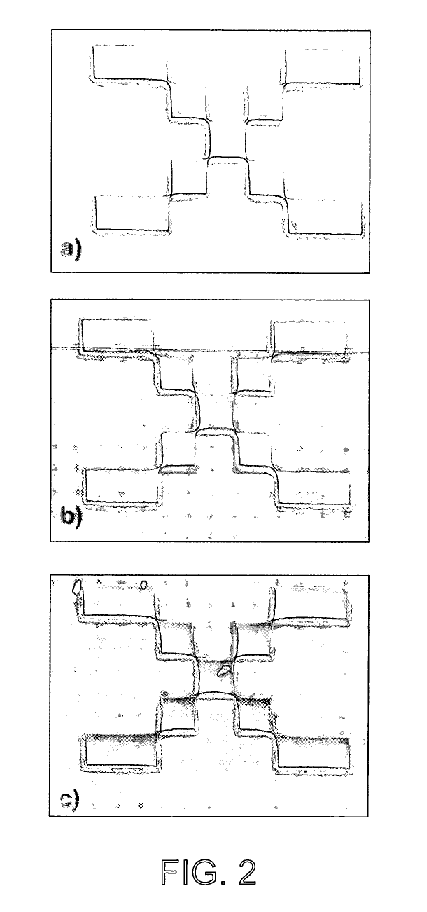

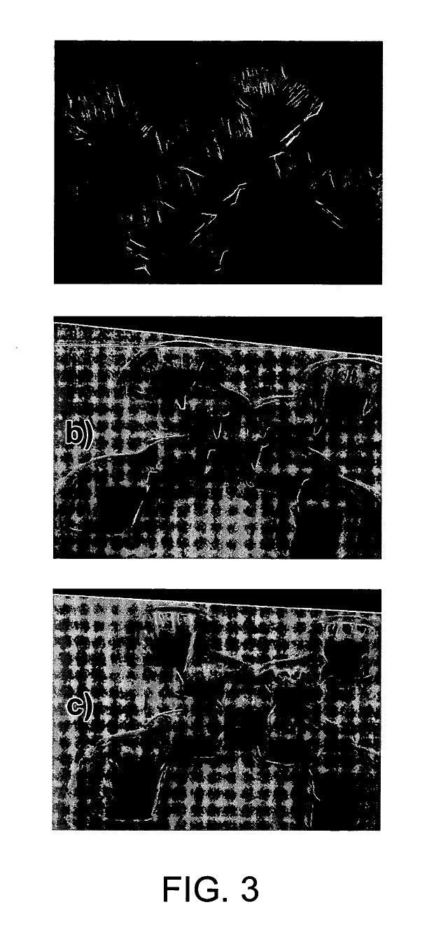

For the 8 μm thick Avatrel® 2000P dose array with the bake and development parameters outlined above, no polymer remained on the wafer for doses of 2-50 mJ/cm². Incomplete polymer pads remained at doses of 50-125 mJ/cm². All pads exposed to 125 mJ/cm² or greater were compatible with subsequent imprinting. Three pads [100, 280, and 460 mJ/cm²] were sputter-coated with gold and examined with scanning electron microscopy and optical profilometry (FIGS. 2A-C and 3A-C, respectively). SEM and profilometry of the 100 mJ/cm² pad show that the imprinted patterns are the same height as the bulk film, but that the bulk film thickness is only 75% of the original film thickness. While the 460 mJ/cm² pad appears to have imprinted very cleanly, see FIGS. 2C and 3C, further investigation showed that the pattern imprinted only half way into the bulk film. The bulk film is, however, 100% of the original film thickness. The middle sample (280 mJ/cm²) maintains the original film thickness and the imprinting appears to penetrate almost completely into the film, FIGS. 2B and 3B, but there is still a need for a descum process if the underlying substrate surface is to be cleanly exposed. The ability to alter the imprinted structures by simply varying the exposure dose exploits a unique feature to the use of this type of photo-crosslinkable material for imprinting. Using the same silicon master in one imprint step with polymer regions exposed to varying doses, both suspended and attached features can be made.

### Example 3

### Fabrication of Microchannels by Combining Imprinting and Sacrificial Materials

As mentioned previously, a unique feature of the negative tone sacrificial polymer system can be exploited by either varying the height of the silicon master or by using different exposure doses so that some imprinted features penetrate nearly all the way to the substrate and others only imprint partway into the film. One type of fluidic device that can be fabricated consists of generating small imprinted features which are suspended inside the photodefined channel structures. A schematic of this process is shown in FIG. 1A. These suspended features have the potential to influence a variety of applications in microfluidics. In a separation device, for example, these constrictions can greatly increase the effective surface area and can provide pore-like properties to the channels by allowing only certain sized objects to experience the restricted areas. Similar structures fabricated with other methods have been examined for entropic trapping and sieving of long DNA strands^{13,14}

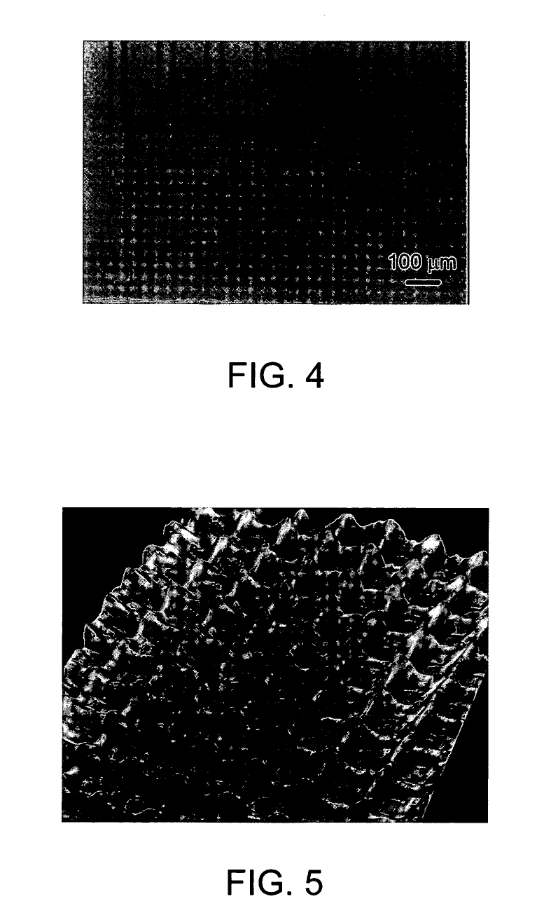

The method depicted in FIG. 1A was used to imprint a serpentine-shaped device structure. An optical micrograph of the patterned structure before imprinting is shown in FIG. 4. After imprinting, the pattern can be seen distinctively by optical profilometry (FIG. 5) and SEM (FIG. 6C). The master is replicated with very little deviation and the imprint depth is approximately half the height of the master which was 5.0-5.5 μm tall for the experiment shown in these figures.

Once the posts were imprinted into the sacrificial material, the channels were encapsulated by a polyimide. Channels made with a thin (1-3 μm) film of polyimide (PI2556) collapsed as seen in FIG. 7. When a thicker polyimide overcoat was used, however, fully encapsulated channels were produced with 1-2 μm posts suspended at a depth of 2.5 μm into the channel (FIG. 8). Thus, a novel method for fabricating a microchannel with suspended microposts has been demonstrated.

If the imprint masters are allowed to penetrate the entire depth of the photodefined channels, then a second type of microfluidic device can be made. By increasing the imprint depth and adding a plasma descum step to the fabrication flow channels with pillar-like obstructions throughout the channel can be produced if posts are printed. This type of structure is similar to the microfabricated monoliths that have been used for capillary electrochromatrography (CEC)¹⁵. To demonstrate this process for a proof of concept, Polymer III/TPS-C1, a polycarbonate photodefinable sacrificial material, was patterned, overcoated with a UV-curable epoxy, and decomposed. The patterned polymer was imprinted before the overcoat was applied and the resulting structure is shown in FIG. 9. The master used for this experiment had 4 μm wide posts with a pitch of approximately 6.5 μm. The micrograph of FIG. 9 was taken after decomposing the sacrificial material, revealing smaller channels within the relief structure.

### Example 4

### Fabrication of Microfluidic Channels

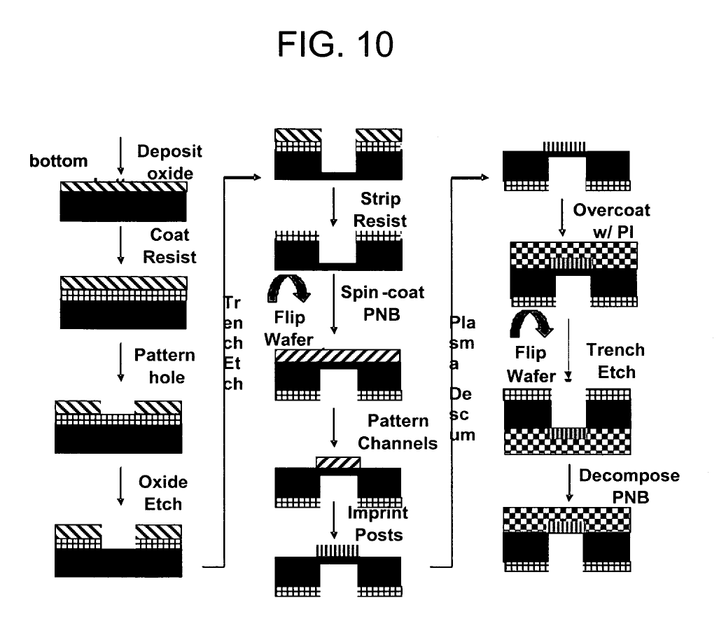

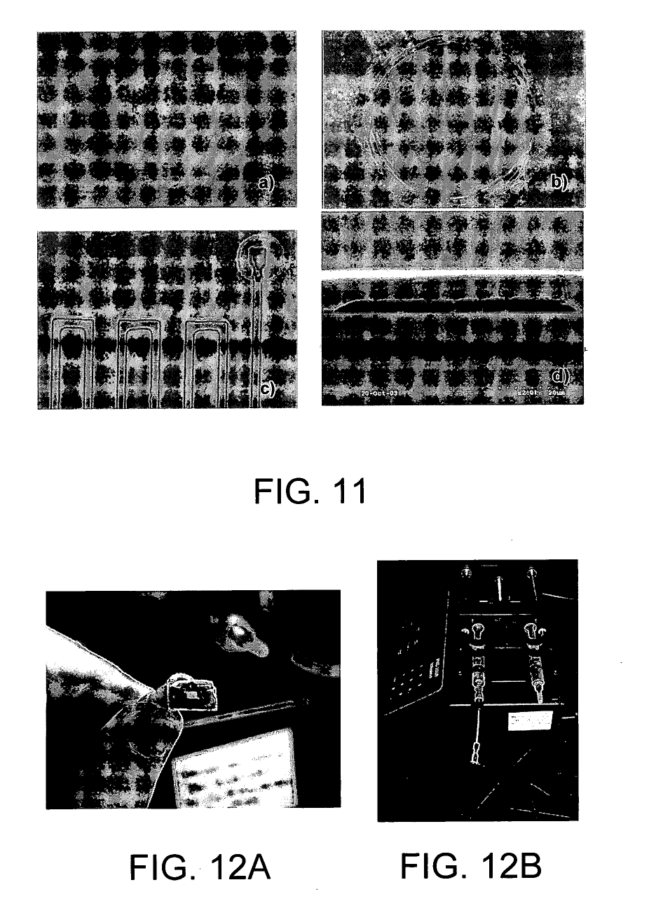

Preliminary fabrication of microfluidic channels utilizing photopatterned sacrificial materials and hot embossing was performed to confirm the validity of the method described above. A typical process flow is shown in FIG. 10. Deep silicon plasma etching of holes through 80-90% of the silicon substrate is first performed to eventually provide ports for plumbing to external fluids. The wafer is then flipped over and the sacrificial material (Avatrel® 2000P) was spin cast, patterned, and imprinted as described previously. A brief plasma descum is required to remove residual polymer remaining at the bottom of the imprinted structures and to remove aid in adhesion of the polyimide overcoat (Pyralin® PI2525). After preliminary curing of the overcoat, the wafer is flipped back over and mounted to a second silicon wafer so that the backside holes can be etched through the remaining substrate. Several micrographs of the completed channel structures can be seen in FIGS. 11A-D. The fabricated channels can then be plumbed using fittings from Upchurch Scientific, Omnifit, or other companies or Sandia National Laboratories° CapTite™ and ChipTite™ microfluidic fittings (FIG. 12). Polymer based fittings of PTFE, PEEK, Teflon, Tefzel, Delrin, PPS, polypropylene or other materials can be bonded to the channel structures and connected to a receiving port with cone or flat-bottom fittings and often Teflon tubing.

### Example 5

### Additional Application Areas

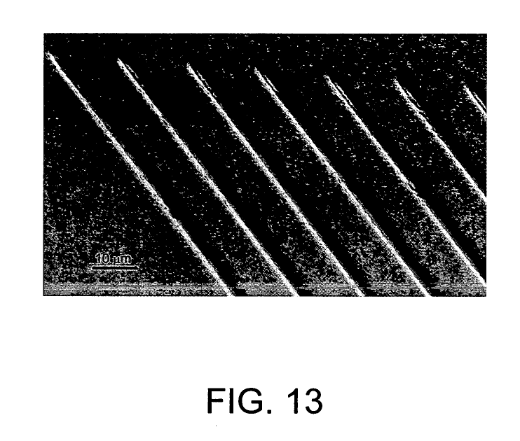

If channels are imprinted instead of posts, then an additional feature of this technique is realized. There are several applications in the analysis of biological molecules where it is advantageous to have a device with microfluidics and nanofluidics on a single device. The technique outlined in FIG. 10 can easily accomplish this goal if nanoscale channels are imprinted into pre-patterned microchannels. This technique can also help increase the resolution of materials such as the photosensitive polycarbonates. For 1:1 line/space patterns, the resolution of these systems varies from approximately 10 μm for the tertiary and secondary PCs up to 90 μm for poly(propylene carbonate) (PPC). Since these polymers are ideal for low-temperature or even room-temperature imprinting because of their low glass transition temperatures, improving the minimum channel size possible with these materials could extend their use to additional applications and even nanofluidics. PPC was imprinted with micron-sized channels to test the validity of this idea. The results of this test are shown in FIG. 13. Imprinting with 35 MPa over a range of temperatures from 50-120° C. revealed that embossing at 80° C. for 90 sec replicated trenches into PPC. Lines with a pitch of 10 μm were successfully imprinted into PPC/TPS-C1 which had been previously lithographically patterned into a 1 cm square.

It should be emphasized that the above-described embodiments of this disclosure are merely possible examples of implementations, and are set forth for a clear understanding of the principles of this disclosure. Many variations and modifications may be made to the above-described embodiments of this disclosure without departing substantially from the spirit and principles of this disclosure. All such modifications and variations are intended to be included herein within the scope of this disclosure and protected by the following claims.

References

1. Cao, Han, et al., Appl. Phys. Lett., 81(1), 174-176 (2002).

2. Montelius, L., et al., Microelectron. Eng., 53, 521-524 (2000).

3. Pepin, A., et al., Microelectron. Eng., 61-62, 927-932 (2002).

4. Sotomayor Torres, C. M., et al., Materials Science & Engineering, C, C23, 23-31 (2003).

5. Pfeiffer, K., et al., Microelectron. Eng., 57-58, 381-387 (2001).

6. Schulz, Hubert, et al., Proc. SPIE-Int. Soc. Opt. Eng., 4688(Pt. 1), 223-231 (2002).

7. Li, Wanli, et al., Nanotechnology, 14, 578-583 (2003).

8. Rowland, Harry D., et al., Transducers '03 Late News, submitted (2003).

9. Wu, Xiaoqun, et al., J. Electrochem. Soc., 149(10), G555-G561 (2002).

10. Wu, Xiaoqun, et al., J. Appl. Polym. Sci., 88(5),1186-1195 (2003).

11. Bai, Yiqun, et al., International Symposium on Advanced Packaging Materials: Processes, Properties, and Interfaces. 2001. Braselton, Ga.: IEEE.

12. Chiniwalla, Punit, et al., J. Appl. Polym. Sci., 89(2), 568-577 (2003).

13. Han, J. and H. G. Craighead, J. Vac. Sci. Technol., A, 17(4), 2142-2147 (1 999).

14. Han, J. and H. G. Craighead, Science, 288, 1026-1029 (2000).

15. He, Bing, et al., Anal. Chem., 70(18), 3790-3197 (1998).

1. A method for producing a patterned structure comprising:
(a) disposing a sacrificial material on a substrate in a relief pattern;
(b) imprinting the sacrificial material;
(c) covering the sacrificial material with a second material; and
(e) selectively removing at least a portion of the sacrificial material to form a negative of the imprinted sacrificial material in the second material.

2. The method of claim 1, wherein the sacrificial material is thermally sacrificial, chemically sacrificial, electrically sacrificial, or photo-sacrificial.

3. The method of claim 1, wherein the sacrificial material is a negative tone material or a positive tone material.

4. The method of claim 1, wherein the sacrificial material is selected from the group consisting of polynorbornenes, polycarbonates, functionalized compounds of each, a copolymer of polynorbornene and polynorbornene carbonate, and combinations thereof.

5. The method of claim 1, wherein the second material is selected from the group consisting of polyimides, polynorbornenes, epoxides, polyarylenes ethers, polyarylenes, plastic, thermoplastic, elastomers, polysiloxanes, acrylates, polymethacrylates, inorganic glasses, and combinations thereof.

6. The method of claim 1, wherein the imprinting has a depth that penetrates to the substrate.

7. The method of claim 1, wherein the imprinting is increased by plasma descum.

8. The method of claim 1, wherein the second material encapsulates the sacrificial material.

9. The method of claim 1, wherein removal of the sacrificial material forms a chamber.

10. The method of claim 1, wherein the negative of the sacrificial material forms a first channel having at least one dimension from about 1 to about 150 μm.

11. The method of claim 10, wherein the imprinting forms at least a second channel within the first channel.

12. The method of claim 10, wherein the imprinting results in at least one structure of about 20 to about 150 nm in at least one dimension.

13. The method of claim 1, wherein removal of the sacrificial material occurs by converting the sacrificial material into a fluid.

14. The method of claim 13, wherein the fluid moves through the substrate or the second material.

15. The method of claim 14, wherein the fluid moves through a pore, channel, vent, or opening in the second material or substrate.

16. The method of claim 1, wherein the imprinted relief pattern is formed by lithography.

17. The method of claim 16, wherein the lithography is selected from the group consisting of chemical lithography, electron beam lithography, ion beam lithography, x-ray lithography, thermal lithography, photolithography, wet etching, and ion beam etching.

18. A channel formed by the method of claim 1.

19. A device comprising:
a void disposed in a housing, the void formed by
disposing a sacrificial material in a relief pattern on a surface of the housing;
imprinting the relief pattern to form a second pattern;
covering the imprinted relief pattern with a second material; and
selectively removing at least a portion of the sacrificial material to form the void.

20. The device of claim 19, wherein the void comprises a microfluidic channel.

21. The device of claim 19, wherein the void is partitioned.

22. The device of claim 19, wherein the void comprises a plurality of posts in an ordered array.

23. The device of claim 19, wherein the void is linear, non-linear, serpentine, or arcuate.

24. The device of claim 19, further comprising at second layer disposed on the second material.

25. The device of claim 24, wherein the second layer comprises a second void.

26. The device of claim 25, wherein the second void is formed by the method of claim 1.

27. A method for producing a microfluidic device comprising:
(a) disposing a sacrificial material on a substrate in a relief pattern, wherein the relief pattern has a relief thickness of about 1 to about 500 μm;
(b) imprinting the relief pattern to form a second pattern, wherein the second pattern comprises an imprint depth of about 1 to about 500 μm;
(c) covering the imprinted relief pattern with a second material; and
(d) selectively removing a least a portion of the sacrificial material to form a microchannel comprising a dimension of about 1 to about 500 μm.

28. The method of claim 27, wherein the second pattern comprises an imprint depth of less than 500 μm to form a protrusion in the microchannel.

29. The method of claim 27, further comprising the step of increasing imprint depth by laser descum.

30. The method of claim 27, wherein the imprint depth is equal to the relief thickness to form a partition in the microchannel.

31. A method for producing a patterned structure comprising:
(a) disposing a sacrificial material on a substrate;
(b) imprinting the sacrificial material to form a first pattern;
(c) removing at least a portion of the sacrificial material to form a second pattern;
(d) covering the sacrificial material with a second material; and
(e) removing the remaining sacrificial material to form a negative of the sacrificial material in the second material.

32. The method of claim 31, wherein the sacrificial material is thermally sacrificial, chemically sacrificial, electrically sacrificial, or photo-sacrificial.

33. The method of claim 31, wherein the sacrificial material is a negative tone material or a positive tone material.

34. The method of claim 31, wherein the sacrificial material is selected from the group consisting of polynorbornenes, polycarbonates, functionalized compounds of each, a copolymer of polynorbornene and polynorbornene carbonate, and combinations thereof.

35. The method of claim 31, wherein the second material is selected from the group consisting of polyimides, polynorbornenes, epoxides, polyarylenes ethers, polyarylenes, plastic, thermoplastic, elastomers, polysiloxanes, acrylates, polymethacrylates, inorganic glasses, and combinations thereof.

36. The method of claim 31, wherein the imprinted pattern has a depth that penetrates to the substrate.

37. The method of claim 31, wherein the depth of the imprinted pattern is increased by plasma descum.

38. The method of claim 31, wherein the second material encapsulates the imprinted pattern.

39. The method of claim 31, wherein removal of the remaining sacrificial material forms a chamber.

40. The method of claim 31, wherein the negative of the imprinted pattern forms a first channel having at least one dimension from about 1 to about 150 μm.

41. The method of claim 40, wherein the second pattern forms at least a second channel within the first channel.

42. The method of claim 40, wherein the second pattern forms at least one structure of about 20 to about 150 nm in at least one dimension.

43. The method of claim 31, wherein removal of the sacrificial material occurs by converting the sacrificial material into a fluid.

44. The method of claim 43, wherein the fluid moves through the substrate or the second material.

45. The method of claim 44, wherein the fluid moves through a pore, channel, vent, or opening in the second material or substrate.

46. The method of claim 31, wherein the second pattern is formed by lithography.

47. The method of claim 46, wherein the lithography is selected from the group consisting of chemical lithography, electron beam lithography, ion beam lithography, x-ray lithography, thermal lithography, photolithography, wet etching, and ion beam etching.
